(19) United States
(12) Patent Application Publication
(10) Pub. No.: US 2012/0168808 A1
(43) Pub. Date: Jul. 5, 2012

(54) PACKAGE STRUCTURE

(75) Inventors: Chia-Leo Lin, Chiayi City (TW); Chuang-Hung Chiu, Hsinchu County (TW); Wei-Jen Tu, Taipei City (TW); Huai-An Li, Taoyuan County (TW)

(73) Assignee: CHUNGHWA PICTURE TUBES, LTD., Taoyuan (TW)

(21) Appl. No.: 13/149,923

(22) Filed: Jun. 1, 2011

(30) Foreign Application Priority Data
Dec. 30, 2010 (TW) 99225578

(51) Int. Cl. H01L 33/48

(52) U.S. Cl. 257/99; 257/E33.056

(57) ABSTRACT

A package structure including a first substrate, a second substrate and a light emitting diode is provided. The first substrate has at least a first annular engaged portion. The second substrate is disposed above the first substrate and has at least a second annular engaged portion. The light emitting diode is disposed on the first substrate. The second annular engaged portion is infixed to the first annular engaged portion so as to form an airtight space. The light emitting diode is located in the airtight space.

### CROSS-REFERENCE TO RELATED APPLICATION

This application claims the priority benefit of Taiwan application serial No. 99225578, filed on Dec. 30, 2010. The entirety of the above-mentioned patent applications is hereby incorporated by reference herein and made a part of this specification.

### BACKGROUND OF THE INVENTION

1. Field of Invention

The present invention generally relates to a semiconductor structure, and more particularly, to a package structure.

2. Description of Related Art

With the advantage of science and technology, flat displays draw most attention in the technique field of display recently. The organic electro-luminescence display apparatus, with advantages such as self-luminescence, wide view angle, low power consumption, simple manufacturing process, low cost, low work temperature range, high responsive speed and full colors, has a great potential of becoming the mainstream flat panel display product in its next generation. An organic light emitting diode mainly comprises a pair of electrodes and an organic material layer sandwiched between the two electrodes. When current flows between the anode and the cathode, electrons and holes in the organic layer are recombined to produce excitons, which enables the organic layer to produce lights with different colors depending on the material property of the organic layer. Thus, a luminous display is achieved.

The organic material and the cathode of the organic light emitting diode are likely to react with moisture and oxygen in the air, which leads performance decay of the organic light emitting diode. Thus, removing the moisture to improve durability of the organic electro-luminescence display panel is an important issue. In general, the organic light emitting diode is fabricated by performing a film coating process in vacuum circumstance, and then the organic light emitting diode is sealed by performing a package process. An organic light emitting diode device is fabricated in high vacuum circumstance, but however, is then brought from the high vacuum circumstance to an environment with moisture and oxygen to perform an upper cover package process, wherein the moisture may infiltrate into the organic light emitting diode and decrease the life time of the organic light emitting diode device.

Conventional package techniques using rigid plates such as glass plates may adopt drier in devices to reduce the infiltration of moisture. Nonetheless, a flexible organic light emitting diode device provides no space for containing drier. In addition, the drier can not effectively and completely prevent the organic light emitting diode from the infiltration of moisture and oxygen. Furthermore, a sealant may be coated around the upper cover, however, the material of the sealant is polymer with high infiltration rate and incapable of preventing the external moisture and oxygen from infiltrating into the device, and thus the life time of the organic light emitting diode is shortened.

### SUMMARY OF THE INVENTION

The present invention provides a package structure capable of preventing a life time of an light emitting diode from being shortened due to infiltration of moisture and oxygen.

As embodied and broadly described herein, a package structure including a first substrate, a second substrate and a light emitting diode is provided. The first substrate has at least a first annular engaged portion. The second substrate is disposed above the first substrate and has at least a second annular engaged portion. The light emitting diode is disposed on the first substrate, wherein the second annular engaged portion is infixed to the first annular engaged portion to form an airtight space, and the light emitting diode is located in the airtight space.

According to an embodiment of the present invention, the first annular engaged portion is an annular grooved portion, while the second annular engaged portion is an annular protruding portion.

According to an embodiment of the present invention, a cross-sectional profile of the above annular grooved portion or the above annular protruding portion is square, rectangular, curved, triangular, or undulating.

According to an embodiment of the present invention, the first annular engaged portion is an annular protruding portion, while the second annular engaged portion is an annular grooved portion.

According to an embodiment of the present invention, a cross-sectional profile of the above annular grooved portion or the above annular protruding portion is square, rectangular, curved, triangular, or undulating.

According to an embodiment of the present invention, a material of the first substrate and the second substrate comprises a glass or a flexible material.

According to an embodiment of the present invention, the flexible material comprises a plastic.

According to an embodiment of the present invention, the package structure further comprises an adhesive layer disposed between the first annular engaging portion and the second annular engaging portion.

According to an embodiment of the present invention, the at least one first annular engaging portion comprises a plurality of first annular engaging portions, and the at least one second annular engaging portion comprises a plurality of second annular engaging portions. The first annular engaging portions are spaced in equidistance from one another, and the second annular engaging portions are spaced in equidistance from one another.

In an embodiment of the present invention, the light emitting diode is an organic light emitting diode.

As to the above, the first substrate and the second substrate of the present invention are mounted by engaging the first annular engaging portion and the second annular engaging portion. Thus, the infiltrating path of the moisture and the oxygen is prolonged so as to alleviate the infiltration of the moisture and the oxygen. The package structure of the present invention has superior resistance to moisture and oxygen to improve the life time of the light emitting diode.

In order to make the aforementioned and other features and advantages of the invention more comprehensible, several embodiments accompanied with figures are described in detail below.

### BRIEF DESCRIPTION OF THE DRAWINGS

The accompanying drawings constituting a part of this specification are incorporated herein to provide a further understanding of the invention. Here, the drawings illustrate embodiments of the invention and, together with the description, serve to explain the principles of the invention.

FIG. 1A is a cross-sectional view of a package structure according to an embodiment of the present invention.

FIG. 1B is a schematic three-dimensional view of a first substrate of the package structure in FIG. 1A.

FIG. 1C is a schematic three-dimensional view of a second substrate of the package structure in FIG. 1A.

FIG. 2 is a cross-sectional view of a package structure according to another embodiment of the present invention.

### DESCRIPTION OF EMBODIMENTS

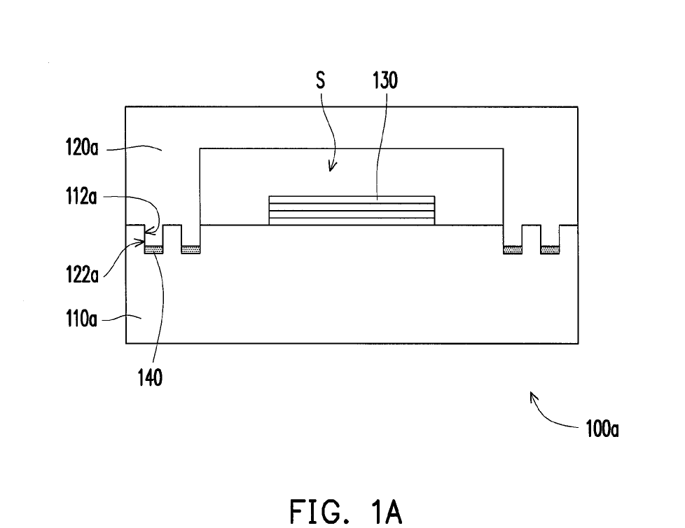

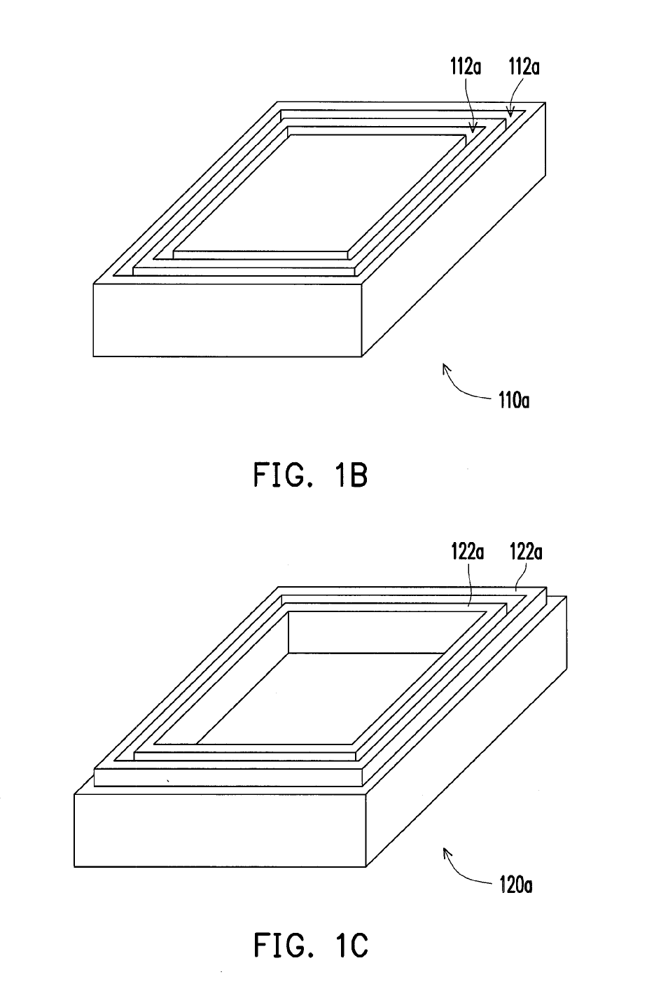

FIG. 1A is a cross-sectional view of a package structure according to an embodiment of the present invention. FIG. 1B is a schematic three-dimensional view of a first substrate of the package structure in FIG. 1A. FIG. 1C is a schematic three-dimensional view of a second substrate of the package structure in FIG. 1A. Referring to FIGS. 1A, 1B and 1C, in the present embodiment, the package structure 100a comprises a first substrate 110a, a second substrate 120a and a light emitting diode 130.

Specifically, the first substrate 110a has at least one first annular engaging portion 112a (here exemplarily shows two in FIGS. 1A through 1C), and the first annular engaging portions 112a are spaced in equidistance from one another. The material of the first substrate 110a may be a glass or a flexible material comprises polyethylene (PE) series plastic, polymethylmethacrylate (PMMA), polycarbonate (PC) or polyimide (PI). For example, the PE series plastic can be chlorinated polyethlene (PEC), polyethylene naphthalate (PEN), polyethersulfone (PES) etc.

The second substrate 120a is disposed above the first substrate 110a, and the second substrate 120a has at least one second annular engaging portion 122a (here exemplarily shows two in FIGS. 1A through 1C), wherein the second annular engaging portions 122a are spaced in equidistance from one another. The material of the second substrate 120a may be a glass or a flexible material comprises polyethylene (PE) series plastic, polymethylmethacrylate (PMMA), polycarbonate (PC) or polyimide (PI). For example, the PE series plastic can be chlorinated polyethlene (PEC), polyethylene naphthalate (PEN), polyethersulfone (PES) etc.

The light emitting diode 130 is disposed on the first substrate 110a, wherein the second annular engaging portion 122a is infixed to the first annular engaged portion 112a to form an airtight space S, and the light emitting diode 130 is located in the airtight space S. In the present embodiment, the light emitting diode 130 may be an organic light emitting diode but not limited thereto.

In the present embodiment, the first annular engaging portions 112a may be annular grooved portions, and the second annular engaging portions 122a may be annular protruding portions, wherein the cross-sectional profile of the annular grooved portions or the annular protruding portions may be rectangular. It should be noted that, although the first annular engaging portions 112a and the second annular engaging portions 122a are respectively presented as the annular grooved portions and the annular protruding portions, the present invention provides no restriction on the profiles of the first annular engaging portions 112a and the second annular engaging portions 122a. In other embodiments, the first annular engaging portions 112a being annular protruding portions and the second annular engaging portions 122a being annular grooved portions are still techniques proposed by the present invention and do not depart from the spirit of the invention.

In order to enhancing the connection between the first substrate 110a and the second substrate 120a, the package structure 100a of the present invention may further comprise an adhesive later 140 disposed between the first annular engaging portions 112a and the second annular engaging portions 122a to improve the reliability in bonding the first annular engaging portions 112a and the second annular engaging portions 122a.

Accordingly, since the first substrate 110a and the second substrate 120a are assembled by infixing the first annular engaging portion 112a to the second annular engaging portion 122a, the infiltrating path of the moisture and the oxygen entering the package structure 100a is prolonged by the first annular engaging portion 112a and the second annular engaging portion 122a, so as to alleviate the infiltration of the moisture and the oxygen. Therefore, the package structure 100a of the present embodiment has superior resistance to moisture and oxygen to improve the life time of the light emitting diode 130.

Another embodiment is provided hereinafter to illustrate a package structure 100b. To facilitate illustration and comprehension of the disclosure, same reference numbers mentioned above are used in the following embodiment to represent same or similar elements, and repetitive explanation is likely to be omitted. The omitted descriptions can be referred to the above embodiment and are not repeated in the following embodiment.

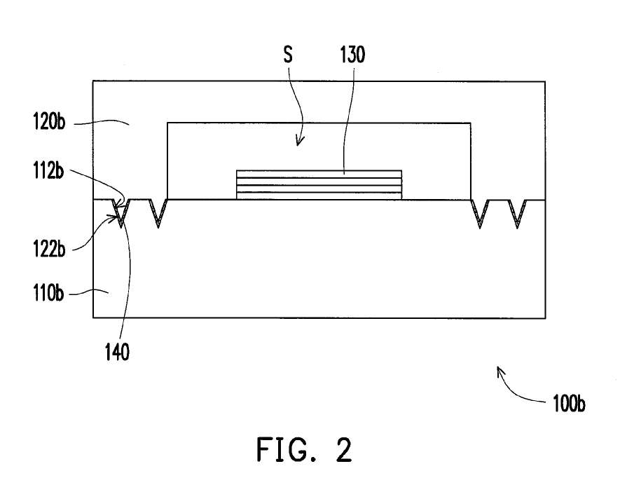

FIG. 2 is a cross-sectional view of a package structure according to another embodiment of the present invention. Referring to FIG. 2, the package structure 100b is similar to the package structure 100a of the above embodiment except that: the cross-sectional profiles of the first annular engaging portions 112b (i.e. the annular grooved portions) of the first substrate 110b and the second annular engaging portions 122b (i.e. the annular protruding portions) of the second substrate 120b can be triangular. In other words, the cross-sectional profiles of the annular grooved portions and the annular protruding portions are not limited in the present embodiment and can be rectangular, triangular, square, curved, undulating or other applicable profiles. Structural designs capable of prolonging the infiltrating path of the moisture and the oxygen are techniques proposed by the present invention and do not depart from the spirit of the invention.

Accordingly, the first substrate and the second substrate of the present invention are assembled by infixing the first annular engaging portion to the second annular engaging portion, so as to prolong the infiltrating path of the moisture and the oxygen and alleviate the infiltration of the moisture and the oxygen. Therefore, the package structure of the present embodiment has superior resistance to moisture and oxygen to improve the life time of the light emitting diode.

Although the invention has been described with reference to the embodiments thereof, it will be apparent to one of the ordinary skills in the art that modifications to the described embodiments may be made without departing from the spirit of the invention. Accordingly, the scope of the invention will be defined by the attached claims not by the above detailed description.

What is claimed is:

1. A package structure, comprising:
a first substrate, having at least one first annular engaged portion;
a second substrate, disposed above the first substrate and has at least one second annular engaged portion;
a light emitting diode, disposed on the first substrate, wherein the second annular engaged portion is infixed to the first annular engaged portion to form an airtight space, and the light emitting diode is located in the airtight space.

2. The package structure of claim 1, wherein the first annular engaged portion is an annular grooved portion, while the second annular engaged portion is an annular protruding portion.

3. The package structure of claim 2, wherein a cross-sectional profile of the annular grooved portion or the annular protruding portion is square, rectangular, curved, triangular, or undulating.

4. The package structure of claim 1, wherein the first annular engaged portion is an annular protruding portion, while the second annular engaged portion is an annular grooved portion.

5. The package structure of claim 4, wherein a cross-sectional profile of the annular grooved portion or the annular protruding portion is square, rectangular, curved, triangular, or undulating.

6. The package structure of claim 1, wherein a material of the first substrate and the second substrate comprises a glass or a flexible material.

7. The package structure of claim 6, wherein the flexible material comprises a plastic.

8. The package structure of claim 1, further comprising an adhesive layer disposed between the first annular engaging portion and the second annular engaging portion.

9. The package structure of claim 1, wherein the at least one first annular engaging portion comprises a plurality of first annular engaging portions spaced in equidistance from one another, and the at least one second annular engaging portion comprises a plurality of second annular engaging portions spaced in equidistance from one another.

10. The package structure of claim 1, wherein the light emitting diode is an organic light emitting diode.
